(19) United States
(12) Patent Application Publication
(10) Pub. No.: US 2008/0211392 A1
(43) Pub. Date: Sep. 4, 2008

(54) METHOD OF MANUFACTURING ORGANIC EL ELEMENT

(76) Inventors: Norihisa MAEDA, Ishikawa-gun (JP); Hirofumi Kubota, Kanazawa-shi (JP); Masuyuki Oota, Hakusan-shi (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 11/936,446

(22) Filed: Nov. 7, 2007

(30) Foreign Application Priority Data
Nov. 8, 2006 (JP) 2006-303037

(51) Int. Cl. H01J 1/62; H01L 51/50; H01L 51/52

(52) U.S. Cl. 313/504; 428/408; 428/336; 428/917

(57) ABSTRACT

An organic EL element includes a light-transmitting cathode, an emitting layer, and an anode facing the cathode with the emitting layer interposed therebetween and including a light-reflecting metal material layer and a carbon layer interposed between the metal material layer and the emitting layer.

### CROSS-REFERENCE TO RELATED APPLICATIONS

This application is based upon and claims the benefit of priority from prior Japanese Patent Application No. 2006-303037, filed Nov. 8, 2006, the entire contents of which are incorporated herein by reference.

### BACKGROUND OF THE INVENTION

1. Field of the Invention

The present invention relates to an organic electroluminescence (hereinafter referred to as EL) element and an organic EL display.

2. Description of the Related Art

In an organic EL element, it is advantageous that a material with a large work function is used as the material of the anode. When a material with a high work function is used as the material of the anode, a high hole injection efficiency can be achieved, thus a low drive voltage and a high luminous efficiency can be achieved. For these reasons, many organic EL elements use indium tin oxide (hereinafter referred to as ITO) with a work function of 5.0 eV as the material of the anode.

ITO is a representative transparent conductive oxide. Thus, when a light emitted by the emitting layer is to be output through the cathode, in general, a structure in which a light transmitted through a transparent conductive oxide layer is reflected by a reflecting layer is employed so as to achieve a high outcoupling efficiency. That is, in order to achieve a low drive voltage and a high luminous efficiency, a laminate of a transparent conductive oxide layer and a reflecting layer is used as the anode, or a transparent as the anode and a reflecting layer are utilized in combination.

When the work function of the reflecting layer is sufficiently high, it may be possible to achieve a low drive voltage and a high luminous efficiency without utilizing the transparent conductive oxide layer. However, none of materials commonly used as an electrode has a high work function and can achieve a high reflectance. For example, the work functions of aluminum and silver are 4.3 eV, though a reflectance of 90% or more can be achieve over almost whole the visible light range when aluminum or silver is used. On the other hand, the reflectance of gold for the light within the short wavelength range, in particular, blue range is 40%, though the work function thereof is 5.1 eV.

In this connection, SID 04 DIGEST, p. 682 describes that a surface of a silver anode is oxidized using UV ozone treatment so as to increase a hole injection efficiency while maintaining a high reflectance.

### BRIEF SUMMARY OF THE INVENTION

An object of the present invention is to make it possible to achieve a low drive voltage and a high luminance in an organic EL element in which a light emitted by an emitting layer is output through a cathode.

According to a first aspect of the present invention, there is provided an organic EL element comprising a light-transmitting cathode, an emitting layer, and an anode facing the cathode with the emitting layer interposed therebetween and including a light-reflecting metal material layer and a carbon layer interposed between the metal material layer and the emitting layer.

According to a second aspect of the present invention, there is provided an organic EL display comprising first and second pixels different in luminescent colors from each other, each of the first and second pixels including the organic EL element according to the first aspect.

### BRIEF DESCRIPTION OF THE SEVERAL VIEWS OF THE DRAWING

FIG. 1 is a sectional view schematically showing an organic EL element according to an embodiment of the present invention;

FIG. 2 is a plan view schematically showing an example of a display including the organic EL element shown in FIG. 1;

FIG. 3 is a cross sectional view schematically showing an example of a structure that can be employed in the display shown in FIG. 2;

FIG. 4 is a cross sectional view schematically showing another example of a structure that can be employed in the display shown in FIG. 2;

FIG. 5 is a cross sectional view schematically showing an example of an organic EL element; and

FIG. 6 is a graph showing an example of the relation between the thickness of a carbon layer and a drive voltage.

### DETAILED DESCRIPTION OF THE INVENTION

An embodiment of the present invention will be described in detail below with reference to the accompanying drawing. Note that the same reference numerals denote constituent elements that achieve the same or similar functions in the drawing, and a repetitive explanation thereof will be omitted.

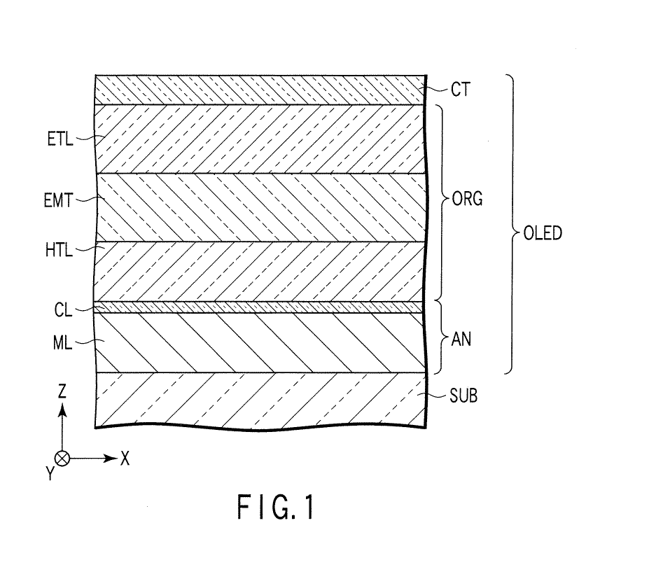

FIG. 1 is a sectional view schematically showing an organic EL element according to an embodiment of the present invention.

The organic EL element OLED includes an anode AN, an organic layer ORG and a cathode CT, and supported by a substrate SUB. The anode AN and the cathode CT face each other. The organic layer ORG is interposed between the anode AN and the cathode CT. Here, as an example, the organic EL element is supported by the substrate SUB such that the anode AN is interposed between the cathode CT and the substrate SUB.

The anode AN has a light-reflecting property and reflects a light emitted by the organic layer ORG. The anode AN includes a metal material layer ML and a carbon layer CL interposed between the metal material layer ML and the organic layer ORG.

The metal material layer ML has a light-reflecting property and reflects the light emitted by the organic layer ORG. As the material of the metal material layer ML, aluminum, silver or an alloy thereof can be used, for example.

The carbon layer is made of amorphous carbon, for example. The ionization potential of amorphous carbon is about 5.3 eV.

As the thickness of the carbon layer CL is decreased, the drive voltage of the organic EL element rises. A sufficiently low drive voltage can be achieved when the thickness of the carbon layer CL is, for example, 2 nm or more. Typically, the thickness of the carbon layer CL is 3 nm or more.

As the thickness of the carbon layer CL is increased, the reflectance of the anode AN is lowered. Typically, the thickness of the carbon layer is 10 nm or less.

The organic layer ORG includes an emitting layer EMT, a hole-transporting layer HTL and an electron-transporting layer ETL. The hole-transporting layer is interposed between the emitting layer EMT and the anode AN. The electron-transporting layer is interposed between the emitting layer EMT and the cathode CT.

The emitting layer EMT is made of a mixture containing a host material and a dopant material, for example. As the host material, tris(8-hydroxy quinolinato)aluminum(III) commonly abbreviated to Alq₃ or 4,4′-di(carbazolyl-9-yl)biphenyl commonly abbreviated to CBP can be used, for example. As the dopant material, tris(2-phenylpyridine)iridium commonly abbreviated to Ir(ppy)₃ can be used, for example.

The hole-transporting layer HTL is made of, for example, N,N′-diphenyl-N,N′-bis(1-napthylphenyl)-1,1′-biphenyl-4,4′-diamine commonly abbreviated to α-NPD. The hole-transporting layer HTL may be omitted.

The electron-transporting layer ETL is made of, for example, Alq₃. The electron-transporting layer ETL may be omitted.

The organic layer ORG may further include an electron-blocking layer between the hole-transporting layer HTL and the emitting layer EMT. Also, the organic layer ORG may further include a hole-blocking layer between the electron-transporting layer ETL and the emitting layer EMT.

The cathode CT has a light-reflecting property and transmits the light emitted by the organic layer ORG. As the material of the cathode CT, an alloy of magnesium and silver can be used, for example.

The organic EL element OLED may further include a hole injection layer between the anode AN and the organic layer ORG. Also, the organic EL element OLED may further include an electron injection layer between the cathode CT and the organic layer ORG.

When the above-described structure is employed, a high hole injection efficiency and a high reflectance can be achieved. Therefore, according to the present embodiment, a low drive voltage and a high luminance can be achieved.

The organic EL element OLED may have a function of an optical resonator. That is, the organic EL element OLED may employ a structure in which a multiple-beam interference of light emitted by the emitting layer occurs between the metal material layer ML and the cathode CT. When such a structure is employed, the luminance and the color purity can be increased.

The organic EL element OLED can be utilized as a light-emitting element of a display, for example.

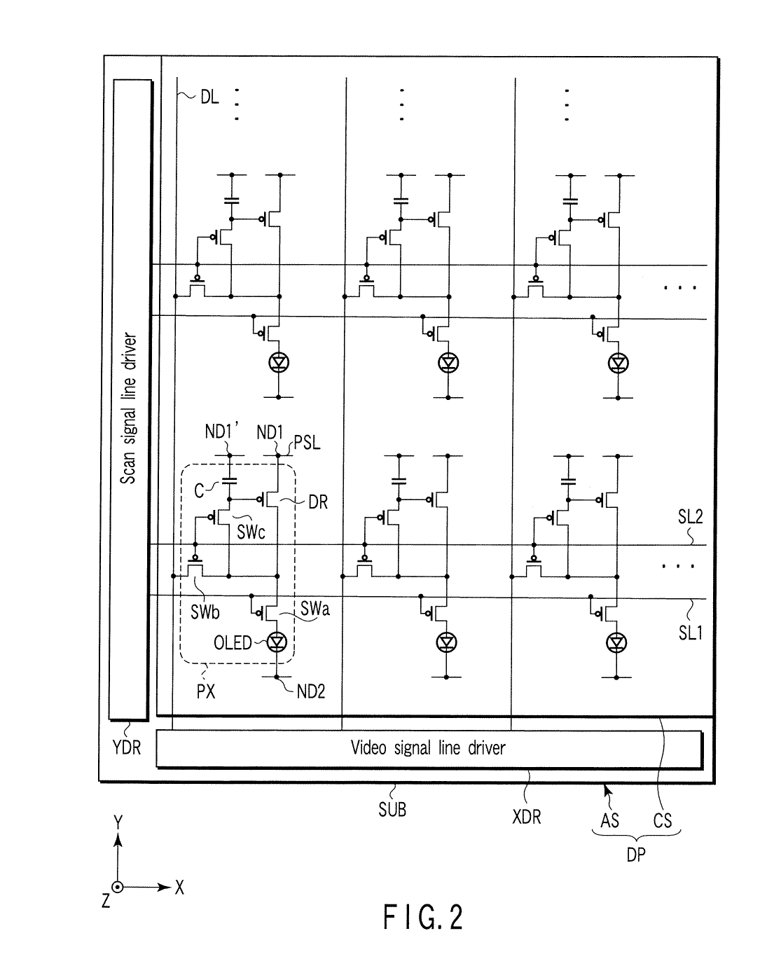

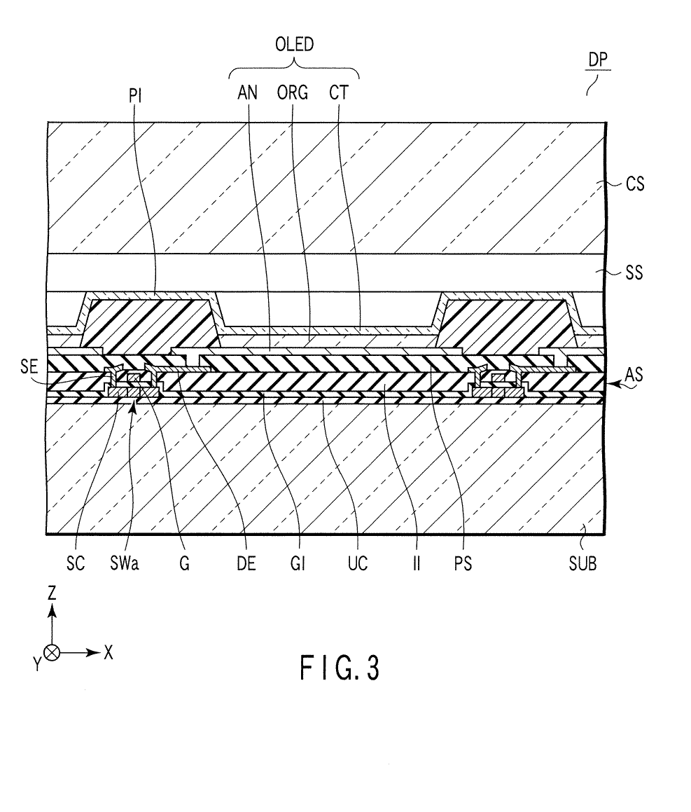

FIG. 2 is a plan view schematically showing an example of a display including the organic EL element shown in FIG. 1. FIG. 3 is a cross sectional view schematically showing an example of a structure that can be employed in the display shown in FIG. 2. In FIG. 3, the display is drawn such that the display surface, i.e., the front surface or the light-emitting surface faces the top of the drawing, and the back surface faces the bottom of the drawing.

The display is a top emission organic EL display employing an active matrix driving method. The organic EL display includes a display panel DP, a video signal line driver XDR, and a scan signal line driver YDR.

As shown in FIGS. 2 and 3, the display panel DP includes an array substrate AS and a sealing substrate CS. The array substrate AS and the sealing substrate CS face each other and forming a hollow body. Specifically, the center portion of the sealing substrate CS is spaced apart from the array substrate AS. The peripheral portion of the sealing substrate CS is adhered to a major surface of the array substrate via a frame-shaped sealing layer SS as shown in FIG. 3.

The array substrate AS includes an insulating substrate SUB such as a glass substrate.

An undercoat layer UC shown in FIG. 3 is formed on the substrate SUB. The undercoat layer UC is, for example, a laminate of a silicon nitride layer and a silicon oxide layer sequentially stacked on the substrate SUB in this order.

A semiconductor pattern made, for example, of polysilicon containing impurities is formed on the undercoat layer UC. Parts of the semiconductor pattern are used as the semiconductor layers SC shown in FIG. 3. In the semiconductor layer SC, impurity diffusion layers used as a source and a drain are formed. The other parts of the semiconductor layer are used as the bottom electrodes of capacitors C to be described later. The bottom electrodes are arranged correspondingly with pixels PX to be described later.

The semiconductor pattern is covered with the gate insulator GI shown in FIG. 3. The gate insulator can be formed, for example, using tetraethyl orthosilicate commonly abbreviated to TEOS.

On the gate insulator GI, the scan signal lines SL1 and SL2 shown in FIG. 2 are formed. The scan signal lines SL1 and SL2 extend in the X-direction parallel with the rows of the pixels PX and are alternately arranged in the Y-direction parallel with the columns of the pixels PX. The scan signal lines SL1 and SL2 are made of MoW, for example. It is noted that the Z-direction is a direction perpendicular to the X-direction and the Y-direction.

On the gate insulator GI, the top electrodes of the capacitors C are further arranged. The top electrodes are arranged correspondingly with the pixels PX and face the bottom electrodes of the capacitors C. The top electrodes are made, for example, of MoW and can be formed in the same step as that for the gates G.

The scan signal lines SL1 and SL2 intersect the semiconductor layers SC. Each intersection portion of the scan signal line SL1 and the semiconductor layer SC constitute the switching transistor SWa shown in FIGS. 2 and 3. The intersection portions of the scan signal line SL2 and the semiconductor layer SC constitute the switching transistors SWb and SWc shown in FIG. 2. The bottom electrodes, top electrodes and those portions of the insulating layer GI interposed therebetween constitute the capacitors C shown in FIG. 2. Each top electrode includes an extension portion extending from the capacitor in the direction perpendicular to the Z-direction such that the extension portion intersects the semiconductor layer. This intersection portion constitutes the drive transistor DR shown in FIG. 2.

It is noted that the drive transistors DR, switching transistors SWa to SWc are top gate-type p-channel thin-film transistors. Note also that the portion indicated with the reference symbol G is the gate of the switching transistor SWa.

The gate insulator GI, the scan signal lines SL1 and SL2, and the top electrodes are covered with the interlayer insulating film II shown in FIG. 3. The interlayer insulating film II is made, for example, of silicon oxide deposited using plasma CVD.

On the interlayer insulating film II, the video signal lines DL and the power supply lines PSL are formed. The video signal lines DL extend in the Y-direction and are arranged in the X-direction. The power supply lines PSL extend in the Y-direction and are arranged in the X-direction, for example.

On the interlayer insulating film II, the source electrodes SE and the drain electrodes DE shown in FIG. 3 are further formed. The source electrodes SE and the drain electrodes DE connect elements to one another in each of the pixels PX.

The video signal lines DL, the power supply lines PSL, the source electrodes SW and the drain electrodes DE have a three-layered structure of Mo/Al/Mo, for example. These components can be formed in the same step.

The video signal lines DL, the power supply lines PSL, the source electrodes SW and the drain electrodes DE are covered with the passivation layer PS shown in FIG. 3. The passivation layer is made, for example, of silicon nitride.

On the passivation layer PS, the anodes shown in FIG. 3 are arranged correspondingly with the pixels PX. The anodes AN are pixel electrodes as back electrode with a light reflecting property. Each anode AN is connected to the drain electrode DE via the through-hole formed in the passivation layer PS, and the drain electrode DE is connected to the drain of the switching transistor SWa.

As described above, the anodes AN include the metal material layer ML and the carbon layer CL shown in FIG. 1. The metal material layer ML is interposed between the passivation layer PS and the carbon layer CL.

The metal material layer ML is patterned correspondingly with the pixels PX. The carbon layer CL may be patterned correspondingly with the pixels PX. Alternatively, the carbon layer CL may be continuous across the pixels PX. For example, the carbon layer CL may be a continuous layer extending over whole the display area, which is an area where the pixels PX are arranged. Since the sheet resistance of the carbon layer CL is sufficiently large, the shorting of the metal material layers ML does not occur.

On the passivation layer PS, the partition insulating layer PI shown in FIG. 3 is further formed. In the partition insulating layer PI, through-holes are formed at positions corresponding to the anodes AN, or slits are formed at positions corresponding to the columns of the anodes AN. Here, as an example, the partition insulating layer PI has through-holes formed at positions corresponding to the anodes AN.

The partition insulating layer PI is, for example, an organic insulating layer. The partition insulating layer PI can be formed using, for example, a photolithography technique.

The partition insulating layer PI may be formed after forming the carbon layer CL. Alternatively, the partition insulating layer PI may be prior to forming the carbon layer CL. In the latter case, damages of the carbon layer CL associated with the formation of the partition insulating layer PI using the photolithography technique can be prevented.

On each anode AN, the organic layer ORG is formed. Each layer in the organic layer ORG may be patterned correspondingly with the pixels PX. Alternatively, each layer in the organic layer ORG may be continuous across the pixels PX.

The partition insulating layer PI and the organic layer ORG are covered with the cathode CT. In this example, the cathode CT is a common electrode shared among the pixels PX. Also, in this example, the cathode CT is a front electrode with a light-transmitting property. The anode is electrically connected to an electrode wiring (not shown) formed on the layer on which the video signal lines DL are formed. Each organic EL element OLED includes the anode AN, the organic layer ORG and the cathode CT.

As shown in FIG. 2, each pixel PX includes the drive transistor DR, the switching transistors SWa to SWc, the organic EL element OLED and the capacitor C. As described above, in this example, the drive transistor DR and the switching transistors SWa to SWc are p-channel thin-film transistors.

The drive transistor DR, the switching transistor SWa and the organic EL element OLED are connected in series between the first power supply terminal ND1 and the second power supply terminal ND2 in this order. In this example, the power supply terminal ND1 is a high-potential power supply terminal, and the power supply terminal ND2 is a low-potential power supply terminal.

The gate of the switching transistor SWa is connected to the scan signal line SL1. The switching transistor SWb is connected between the video signal line DL and the drain of the drive transistor DR, and the gate thereof is connected to the scan signal line SL2. The switching transistor SWc is connected between the drain and gate of the drive transistor DR, and the gate thereof is connected to the scan signal line SL2.

The capacitor C is connected between the gate of the drive transistor DR and the constant-potential terminal ND1′. In this example the constant potential terminal ND1′ is connected to the power supply terminal ND1.

As shown in FIG. 3, the sealing substrate CS faces the substrate SUB with the organic EL elements OLED interposed therebetween. The sealing substrate CS is spaced apart from the cathode CT. The sealing substrate CS is, for example, a glass substrate.

The sealing layer SS is frame-shaped and interposed between the peripheries of the array substrate AS and the sealing substrate CS as described above. The sealing layer surrounds the organic EL elements OLED. As the material of the sealing layer, fritting glass or adhesives can be used, for example.

To the video signal line driver XDR, the video signal lines DL are connected. In this example, power supply lines PSL are further connected to the video signal line driver XDR. The video signal line driver XDR outputs video signals as current signals to the video signal lines, and supply each power supply line PSL with power-supply voltage.

To the scan signal line driver YDR, the scan signal lines SL1 and SL2 are connected. The scan signal line driver YDR outputs first and second scan signals as voltage signals to the scan signal lines SL1 and SL2, respectively.

When an image is to be displayed on the organic EL display, the pixels PX are sequentially selected on a line-by-line basis, for example. In the selection period during which the pixels PX in a certain row are selected, a write operation is executed on each of the selected pixels PX. In the non-selection period during which the pixels PX in a certain row are not selected, a display operation is executed on each of the non-selected pixels PX.

Specifically, in the selection period during which the pixels PX in a certain row are selected, the scan signal line driver YDR outputs a scan signal as a voltage signal for opening the switches SWa, i.e., for making the switches SWa off to the scan signal SL1 to which the selected pixels PX are connected. Subsequently, the scan signal line driver YDR outputs a scan signal as a voltage signal for closing the switches SWb and SWc, i.e., for making the switches SWb and SWc on to the scan signal line SL2 to which the selected pixels PX are connected. In this state, the video signal line driver XDR outputs video signals as current signals (or write current) I_{sig} to the video signal lines DL, so as to set the gate-to-source voltages V_{gs} of the drive transistors DR at values corresponding to the video signals I_{sig}. Then, the scan signal line driver YDR outputs a scan signal as a voltage signal for opening the switches SWb and SWc to the scan signal line SL2 to which the selected pixels PX are connected. Thereafter, the scan signal line driver YDR outputs a scan signal as a voltage signal for closing the switches SWa to the scan signal line SL1 to which the selected pixels PX are connected. This terminates the selection period.

In the non-selection period subsequent to the selection period, the scan signal line driver YDR outputs a scan signal as a voltage signal for closing the switching transistors SWa to the scan signal line SL1 to which the non-selected pixels PX are connected. The switching transistors SWa are kept closed, and the switching transistors SWb and SWc are kept open. During the non-selection period, drive currents I_{drv} flow through the organic EL elements OLED at magnitudes corresponding to the gate-to-source voltages V_{gs} of the drive control elements DR. Each organic EL element OLED emits light at luminance corresponding to the magnitude of the drive current I_{drv}.

When a color image is to be displayed on the organic EL display shown in FIG. 2, the following structure may be employed.

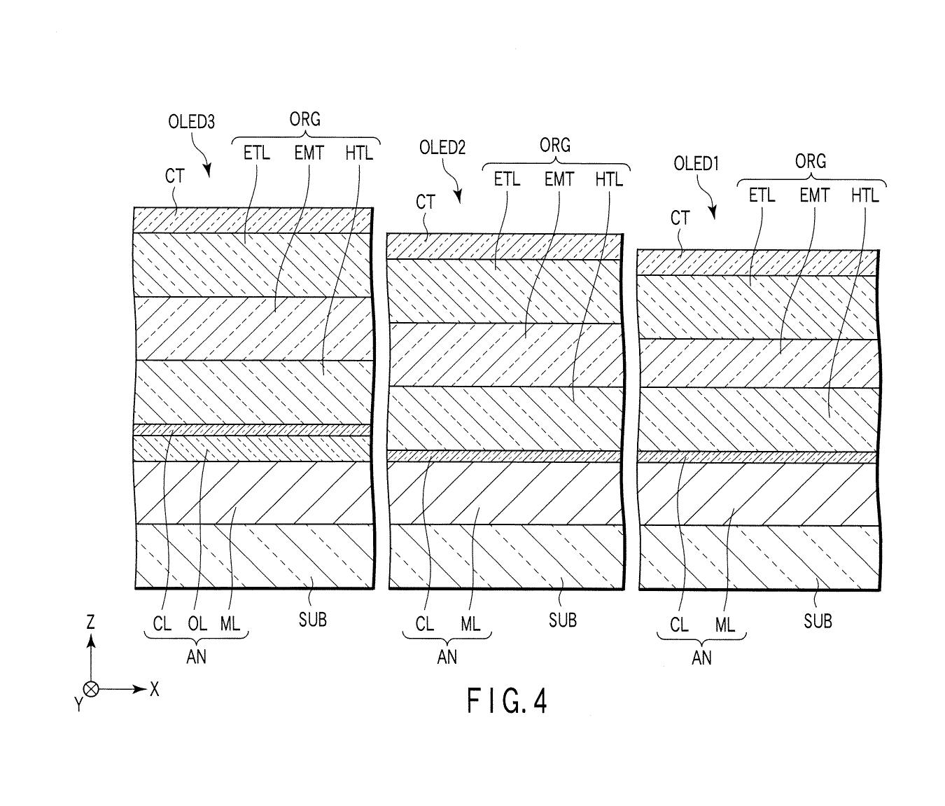

FIG. 4 is a cross sectional view schematically showing another example of a structure that can be employed in the display shown in FIG. 2. In FIG. 4, the reference symbol OLED 1 indicates the organic EL element OLED whose luminance color is blue, the reference symbol OLED 2 indicates the organic EL element OLED whose luminance color is green, and the reference symbol OLED 1 indicates the organic EL element OLED whose luminance color is red.

In order to impart the function of an optical resonator to the organic EL element OLED, the optical length between the metal material layer ML and the cathode CT need to be designed such that a multiple-beam interference of light emitted by the emitting layer EMT occurs between the metal material layer ML and the cathode CT. That is, it is necessary that the above optical lengths of the organic EL elements OLED1 to OLED3 differ from one another.

The emitting layers EMT of the organic EL elements OLED1 to OLED3 are formed separately. Therefore, it is possible to make the optical lengths different among the organic EL elements OLED1 to OLED3. However, the thickness of the emitting layer EMT can not necessarily be set at a desired value because it affects the luminance efficiency, etc.

In FIG. 4, the transparent conductive oxide layer OL is interposed between the metal material layer ML and the carbon layer CL only in the organic EL element OLED3. When such a structure is employed, the optical length can be optimized only by the thickness of the transparent conductive oxide layer OL in the organic EL element OLED3. Thus, when designing the organic EL elements OLED1 and OLED2, it is not necessary to consider the optical length of the organic EL element OLED3. Therefore, when the structure shown in FIG. 4 is employed, the degree of flexibility in the design is increased.

In FIG. 4, the transparent conductive oxide layer is interposed between the metal material layer ML and the carbon layer CL only in the organic EL element OLED3. Alternatively, the transparent conductive oxide layer may be interposed between the metal material layer ML and the carbon layer CL only in each of the organic EL elements OLOED1 and OLED2.

In FIG. 4, the luminance colors of the organic EL elements OLED1 to OLED3 are blue, green and red, respectively. Each luminance color of the organic EL elements OLED1 to OLED3 may be changed among blue, green and red, respectively. Alternatively, other colors may be employed as the luminance colors of the organic EL elements OLED1 to OLED.

In FIGS. 3 and 4, the organic EL element OLED shown in FIG. 1 is applied to the top emission organic EL display. The organic EL element OLED may be applied to a bottom emission organic EL display.

The organic EL display shown in FIG. 2 employs the structure in which a video signal as a current signal is written on each pixel circuit. Alternatively, the structure in which a video signal as a voltage signal is written on each pixel circuit may be employed.

The organic EL display shown in FIG. 2 employs the active matrix driving method. Alternatively, the organic EL element shown in FIG. 1 may be utilized in an organic EL displays employing another driving method such as passive matrix driving method or segment driving method.

Examples of the present invention will be described below.

(Manufacture of Element A)

FIG. 5 is a cross sectional view schematically showing an example of an organic EL element.

The organic EL element OLED was manufactured by the following method.

First, on a glass substrate SUB, a metal material layer ML made of aluminum was formed. Subsequently, on the metal material layer ML, a carbon layer CL having a thickness of 10 Å was formed by sputtering. Then, a hole-transporting layer HTL made of α-NPD and having a thickness of 500 Å and an emitting layer EMT made of ALq₃ and having a thickness of 500 Å were formed by vacuum evaporation in this order. It is noted that the emitting layer EML also serves as the electron-transporting layer. Further, on the emitting layer EML, a cathode CT having a thickness of 150 Å was formed by co-evaporation of magnesium and silver. The ratio of the magnesium evaporation rate with respect to the silver evaporation rate was set at 10:1. The organic EL element OLED was thus completed. Hereinafter, the organic EL element OLED was referred to as “element A”.

Next, the substrate and a sealing substrate (not shown) made of glass were bonded together with an sealing layer (not shown) made of an ultraviolet-curing resin such that the element A faces the sealing substrate. The sealing layer was formed to have a frame shape that surrounds the element A. Further, the sealing layer was irradiated with ultraviolet light so as to harden the ultraviolet-curing resin. The element A was sealed as described above.

(Manufacture of Element B)

The organic EL element OLED shown in FIG. 5 was manufactured by the same method as described on the element A except that the thickness of the carbon layer CL was set at 20 Å. Hereinafter, the organic EL element OLED thus manufactured was referred to as “element B”. The element B was sealed by the same method as described on the element A.

(Manufacture of Element C)

The organic EL element OLED shown in FIG. 5 was manufactured by the same method as described on the element A except that the thickness of the carbon layer CL was set at 30 Å. Hereinafter, the organic EL element OLED thus manufactured was referred to as “element C”. The element C was sealed by the same method as described on the element A.

(Manufacture of Element D)

The organic EL element OLED shown in FIG. 5 was manufactured by the same method as described on the element A except that the thickness of the carbon layer CL was set at 50 Å. Hereinafter, the organic EL element OLED thus manufactured was referred to as “element D”. The element B was sealed by the same method as described on the element A.

(Manufacture of Element E)

The organic EL element OLED shown in FIG. 5 was manufactured by the same method as described on the element A except that the thickness of the carbon layer CL was set at 75 Å. Hereinafter, the organic EL element OLED thus manufactured was referred to as “element E”. The element E was sealed by the same method as described on the element A.

(Manufacture of Element F)

The organic EL element OLED shown in FIG. 5 was manufactured by the same method as described on the element A except that the thickness of the carbon layer CL was set at 100 Å. Hereinafter, the organic EL element OLED thus manufactured was referred to as “element F”. The element F was sealed by the same method as described on the element A.

(Manufacture of Element G)

The organic EL element OLED shown in FIG. 5 was manufactured by the same method as described on the element A except that the carbon layer CL was omitted. Hereinafter, the organic EL element OLED thus manufactured was referred to as “element G”. The element G was sealed by the same method as described on the element A.

(Manufacture of Element H)

The organic EL element OLED shown in FIG. 5 was manufactured by the same method as described on the element A except that an ITO layer having a thickness of 500 Å was formed instead of the carbon layer CL. Hereinafter, the organic EL element OLED thus manufactured was referred to as “element H”. The element H was sealed by the same method as described on the element A.

(Performance Evaluation Tests for the Elements)

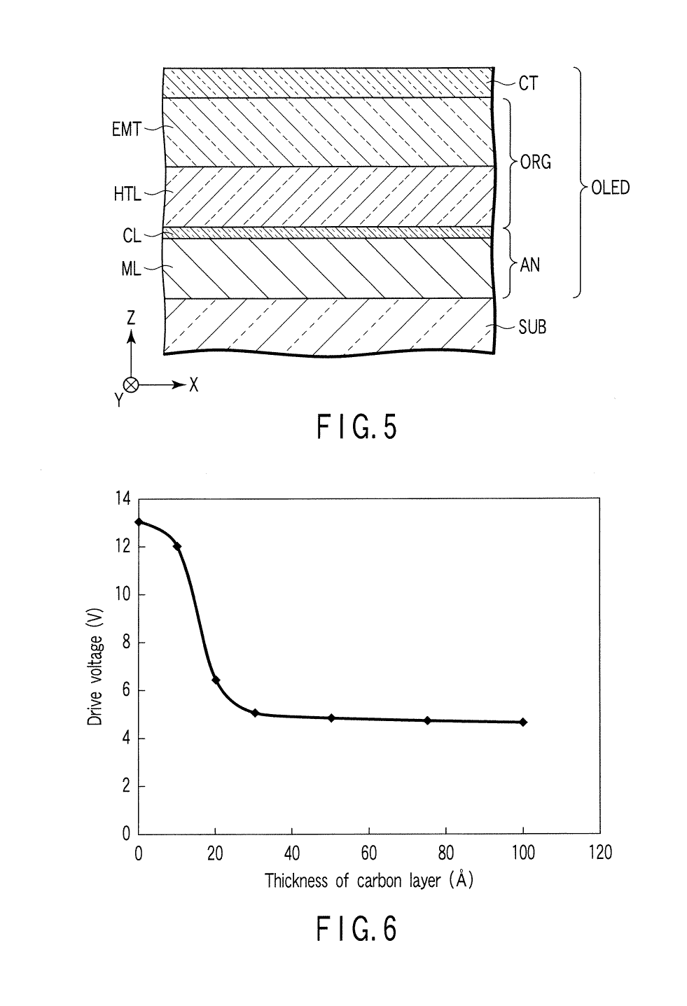

Each of the elements A to H was driven at a current density of 10 mA/cm², and its drive voltage, luminance and chromaticity were measured. The results are summarized in the Table 1 below together with the structures of the elements A to H. Also, the relationship between the thickness of the carbon layer and the drive current is shown in FIG. 6.

TABLE 1

| Element | | | A | B | C | D | E | F | G | H |
|---|---|---|---|---|---|---|---|---|---|---|
| Thickness | Cathode | MgAg | 150 | 150 | 150 | 150 | 150 | 150 | 150 | 150 |
| (Å) | Emitting | Alq₃ | 500 | 500 | 500 | 500 | 500 | 500 | 500 | 500 |
| | layer | | | | | | | | | |
| | Hole-transporting | α-NPD | 500 | 500 | 500 | 500 | 500 | 500 | 500 | 500 |
| | layer | | | | | | | | | |
| | Anode | ITO | — | — | — | — | — | — | — | 500 |
| | | α-C | 10 | 20 | 30 | 50 | 75 | 100 | 0 | — |
| | | Al | 1000 | 1000 | 1000 | 1000 | 1000 | 1000 | 1000 | 1000 |
| Performance | Drive voltage (V) | | 12.0 | 6.35 | 4.97 | 4.78 | 4.66 | 4.59 | 13.1 | 9.2 |
| | Luminance (cd/cm²) | | N.E. | 173 | 133 | 141 | 124 | 134 | N.E. | 28 |
| | Chromaticity | x | | 0.198 | 0.197 | 0.207 | 0.202 | 0.205 | | 0.560 |
| | | y | | 0.519 | 0.515 | 0.547 | 0.519 | 0.533 | | 0.430 |

FIG. 6 is a graph showing an example of the relation between the thickness of a carbon layer and a drive voltage. In the figure, the abscissa represents the thickness of the carbon layer, while the ordinate represents the drive voltage. On the other hand, in Table 1, “x” and “y” represent the chromaticity coordinates x and y of the CIE1931 standard calorimetric system, respectively. Note that “N.E.” in Table 1 represents that no emission was occurred.

As shown in Table 1 and FIG. 6, the drive voltages of the elements B to F are significantly lower than the drive voltages of the elements A and G. In addition, the elements A and G do not emit light, while the elements B to F emit light. These results reveal that the hole injection from the metal material layer made of aluminum into the hole-transporting layer made of α-NPD is difficult, and that the hole injection from the carbon layer into the hole-transporting layer made of α-NPD is possible in the case where the carbon layer is sufficiently thick.

As shown in Table 1, each luminance of the elements B to F is significantly higher than the luminance of the element A. In addition, the drive voltages of the elements B to F are lower than the drive voltage of the element A. That is, the elements B to F achieved a low drive voltage and a high luminance.

(Optical Simulation)

Since carbon absorbs the visible light, as the thickness of the carbon layer is increased, the reflectance of the anode AN is decreased. Then, a reflectance was calculated on the laminate of an aluminum layer and a carbon layer by the optical simulation. The result is summarized in Table 2 below.

TABLE 2

| | | | | | | | | |
|---|---|---|---|---|---|---|---|---|
| Thickness | Carbon | 0 | 10 | 20 | 30 | 50 | 75 | 100 |
| (Å) | layer | | | | | | | |
| | Aluminum | 1000 | 1000 | 1000 | 1000 | 1000 | 1000 | 1000 |
| | layer | | | | | | | |
| Reflect- | 450 nm | 92 | 92 | 92 | 91 | 90 | 88 | 85 |
| ance (%) | 500 nm | 92 | 92 | 92 | 91 | 91 | 89 | 87 |
| | 650 nm | 91 | 91 | 91 | 91 | 90 | 90 | 89 |

Table 2 includes the reflectance for the light having a wavelength of 450 nm as a representative blue light, the reflectance for the light having a wavelength of 500 nm as a representative green light, and the reflectance for the light having a wavelength of 650 nm as a representative red light. As shown in Table 2, when the thickness of the carbon layer is 100 nm or less, the reflectance is 85% or more regardless of the wavelength. Considering that the reflectance of gold for blue light is about 40%, the above reflectance is sufficiently high.

(Evaluations of Carbon Layers on Conductivity)

On a glass substrate, an aluminum layer having a thickness of 1,000 Å, a carbon layer having a thickness of 1,000 Å, and an aluminum layer having a thickness of 1,000 Å were formed in this order by sputtering. The volt-ampere characteristic of the element with the three-layered structure was evaluated. As a result, it was shown that the carbon layer had an electrical conductivity and formed an ohmic contact with the aluminum layers.

Next, a carbon layer was formed by the same method as above, and the resistivity of the carbon layer was determined. As a result, the resistivity was 1.6 MΩcm. This result reveals that the carbon layer can sufficiently act as a part of an electrode and its sheet resistance is sufficiently high when the carbon layer is sufficiently thin.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. An organic EL element comprising:
a light-transmitting cathode;
an emitting layer; and
an anode facing the cathode with the emitting layer interposed therebetween and including a light-reflecting metal material layer and a carbon layer interposed between the metal material layer and the emitting layer.

2. The element according to claim 1, wherein the carbon layer has a thickness of 2 nm or more.

3. The element according to claim 1, wherein the carbon layer has a thickness of 3 nm to 10 nm.

4. The element according to claim 1, wherein the metal material layer is made of aluminum.

5. An organic EL display comprising first and second pixels different in luminescent colors from each other, each of the first and second pixels including the organic EL element according to claim 1.

6. The display according to claim 5, wherein the carbon layer has a thickness of 2 nm or more in each of the first and second pixels.

7. The display according to claim 5, wherein the carbon layer is in contact with the metal material layer in the first pixel, and the anode of the second pixel further includes a transparent conductive oxide layer interposed between the metal material layer and the carbon layer.

8. The display according to claim 5, wherein the carbon layer of the first pixel is connected with the carbon layer of the second pixel.
